(19) United States
(12) Patent Application Publication
(10) Pub. No.: US 2011/0181331 A1
(43) Pub. Date: Jul. 28, 2011

(54) INTEGRATED CIRCUIT WITH LEAKAGE REDUCTION IN STATIC NETS

(75) Inventors: Anubhav SRIVASTAVA, Noida (IN); Anurag GUPTA, Ghaziabad (IN); Sunil K. SINGLA, Ludhiana (IN); Neha SRIVASTAVA, Noida (IN)

(73) Assignee: FREESCALE SEMICONDUCTOR, INC., Austin, TX (US)

(21) Appl. No.: 12/692,640

(22) Filed: Jan. 24, 2010

(51) Int. Cl. H03K 3/00; G06F 17/50

(52) U.S. Cl. 327/215; 716/130; 716/137

(57) ABSTRACT

A method for reducing leakage current of a delay line on a static net is provided. The static net provides a signal communication path between a data output of a first flip-flop and a data input of a second flip-flop via the delay line. The delay line is designed using standard cells but the standard cells are selected based on leakage power consumption in order to reduce the leakage power consumption of the delay line.

### BACKGROUND OF THE INVENTION

The present invention relates generally to integrated circuits (ICs) and more particularly, to leakage power control in integrated circuits.

Integrated circuits include numerous storage elements such as flip-flops and latches. The operation of such storage elements is controlled using clock signals that synchronize the functioning of such digital circuits. The clock signals regulate the storage elements such that the storage elements update their values and perform other operations in a synchronized manner.

As well-known in the art, timing violations such as set-up and hold time violations should be avoided for proper functioning of the various elements of a digital circuit. The set-up time is defined as the time duration prior to clock edge transition that the input signal should be maintained at the level that is desired to be sampled by the digital device. The hold time is the time duration subsequent to the clock edge transition for which the input signal should be maintained at the sampled level. Failing to satisfy either of these timing requirements leads to a timing violation.

In digital circuits, the main cause of set-up and hold timing violations is the different arrival times of the clock and input signals. The clock signal timing may be off due to clock skew, which occurs when the clock signal, generated by a clock generator, reaches different circuit elements at different times due, for example, wire length delays. The clock signal may reach the circuit components physically located near the clock generator before it reaches the circuit components located further away. However, there may be other causes for clock skew such as temperature variations, variation in intermediate devices, capacitive coupling, material imperfections, and so forth.

To synchronize the arrival timings of the clock and input signals at various circuit elements, delay lines are placed in signal paths. The delay lines include delay elements such as buffers and inverters that delay the signal in order to satisfy the set-up and hold requirements of a circuit. The addition of delay lines may also improve upon the fan-out capacity and transition.

One IC component that involves generous use of delay lines is a scan chain. Scan chains are used to test the integrity of the IC subsequent to fabrication. A scan chain includes a plurality of scan cells that are connected such that an output of one scan cell is connected to the input of another. Scan test signals are provided at the IC input pins and the output test signal is obtained at the IC output pins. An input pattern is compared with an output pattern to detect faults in the IC.

Delay lines may be used between two scan cells for eliminating hold time violations. Typically, a delay line originates at the output of a flip-flop of a first scan cell and terminates at the input of a flip-flop of a second scan cell. The scan chains may be put in a scan mode by setting a scan enable (SE) signal. However, although scan chains are rarely used other than during the test stage, the delay lines consume power through-out the life of the chip. Such signal paths or nets that are not toggled during the lifetime of a chip are known as static nets.

There may be other such static nets present in the IC, for example, nets carrying clock gating test signals, reset signals, and boot signals. These signals have high fan-out net routing requirements, and specific timing and skew requirements. Therefore, such signals require delay lines to satisfy set-up and hold time requirements. The buffers/inverters belonging to such delay lines constantly consume leakage power through out the life of the chip. Thus, it would be advantageous if the leakage power consumption of the delay lines belonging to the various static nets in an IC could be reduced.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIGS. 1A and 1B are schematic diagrams illustrating an integrated circuit in accordance with an embodiment of the present invention;

FIGS. 2A and 2B are schematic diagrams illustrating an integrated circuit in accordance with another embodiment of the present invention;

FIG. 3 is a schematic diagram of a flip-flop in accordance with an embodiment of the present invention;

FIG. 4 is a flowchart illustrating a method for designing a delay line on a static net in accordance with an embodiment of the present invention; and

FIG. 5 is a flowchart illustrating a method for designing a delay line on a static net in accordance with another embodiment of the present invention.

### DETAILED DESCRIPTION OF THE PRESENT INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

Each signal described herein may be designed as positive or negative logic, where negative logic can be indicated by a bar over the signal name, an asterix (*) or slash (\) before or after the name, or another manner. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals. In addition, the terms “assert” or “set” and “negate” (or “de-assert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

In an embodiment of the present invention, a method for designing delay lines on a static net is provided, where each of the delay lines includes one or more standard cells. First, the static nets of a circuit are identified from a circuit netlist. Next, static signal values corresponding to the static nets are determined. Thereafter, standard cells for the static nets are selected from a library of standard cells based on leakage power consumptions of the standard cells and the static signal values of the static nets. The selected standard cells then are used to design the delay lines.

In another embodiment of the present invention, a method for designing a delay line formed from standard cells on a static net is provided. The static net includes the path between a data output port of a first flip-flop and a scan input port of a second flip-flop. An output signal from the data output port of the first flip-flop is gated by a scan enable signal to logic 1 and logic 0 based on leakage power consumptions of standard cells in a design library of standard cells. A first standard cell then is selected from the library based on the leakage power consumptions corresponding to the logic levels of the gated output signal. The selected first standard cell is used to design the delay line.

In yet another embodiment, the present invention provides an integrated circuit in which a static net located between the data output of a first flip-flop and the data input of a second flip-flop has the data output of the first flip-flop gated with a scan enable signal. In a further embodiment, a delay line is connected between the data output of the first flip-flop and the data input of the second flip-flop. The delay line includes selected standard cells (buffers and inverters), where the selected standard cells are selected based on their leakage power as it is related to the static net. The selected standard cells are selected because when connected on the static net they have a low leakage power as compared with similar buffer and inverter cells, as the case may be.

Various embodiments of the present invention provide a method of designing a delay line on a static net so that the leakage power consumption of the delay line is low. In an embodiment of the present invention, standard cells are used to design the delay line. The standard cells are selected from a design library such that the selected standard cells for that net have a low leakage power consumption corresponding to the static signal value of the static net. In another embodiment of the present invention, a scan enable signal or a complement scan enable signal is used to gate an output signal to logic 1 or logic 0. The gating of the output signal is accomplished using a NAND, AND or NOR gate. Thereafter, the delay line is designed using delay elements that have the lowest leakage power consumption corresponding to the logic level to which the output signal is gated.

One goal of the present invention is to minimize leakage power consumption of a static net using standard cells. By locating and then analyzing the static nets within an integrated circuit and then selecting those library cells that have a minimum leakage power consumption for a static signal value of the static nets minimizes the leakage power consumption of the delay lines. Additionally, gating of the output signal by either a scan enable signal or the complement scan enable signal reduces dynamic power loss resulting due to futile toggling of the input signal at a scan input port when the scan enable signal is low. Further, the output signal is gated to a desired logic level by the scan enable signal or the complement scan enable signal. The desired logic level is one where the standard cells present in the design library have a minimum leakage power consumption corresponding to that logic level. Thus, the delay line designed using such standard cells will have minimum or low leakage power consumption.

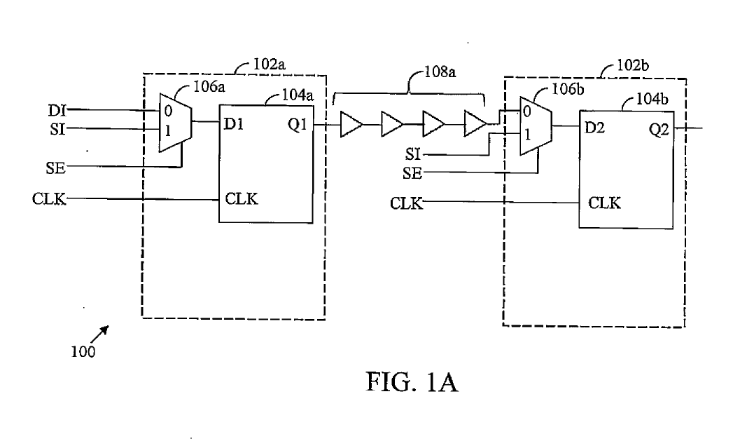

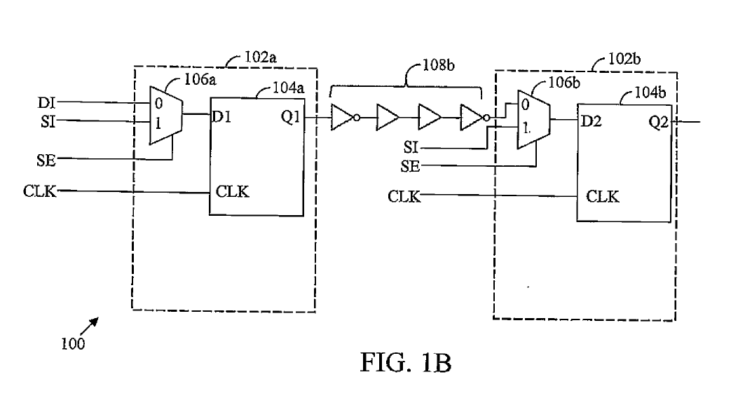

Referring now to FIGS. 1A and 1B, a schematic diagram illustrating an integrated circuit 100 in accordance with an embodiment of the present invention is shown. The integrated circuit 100 includes scan cells 102a and 102b, flip-flops 104a and 104b, multiplexers 106a and 106b, and a buffer chain 108a in FIGS. 1A and 108b in FIG. 1B.

The scan cells 102a and 102b are part of a scan chain that is used to test the integrity of the integrated circuit 100 during the testing stages subsequent to fabrication. A data input signal (DI), a scan input signal (SI), a scan enable signal (SE), and a clock (CLK) signal are provided to the scan cell 102a. The DI, the SI, and the SE signals are received by the multiplexer 106a. The multiplexer 106a selects either the DI signal or the SI signal based on the SE signal. For example, when the SE signal is high, i.e., the scan cells 102a and 102b are in scan mode, the multiplexer 106a selects the SI signal and transmits it to a data input port D1 of the flip-flop 104a. Conversely, if the SE signal is low, the DI signal is selected by the multiplexer 106a and transmitted to the data input port D1 of the flip-flop 104a. In an example, the flip-flop 104a is a D flip-flop. The input signal provided to the flip-flop 104a (the DI signal or the SI signal) appears at a data output port Q1 of the flip-flop 104a, after a predetermined time duration. The data output port Q1 of the flip-flop 104a is connected to a first end of the delay line 108a.

The delay line 108a includes one or more standard cells such as buffers or inverters. The standard cells used to design the delay line 108a are selected based on the leakage power consumptions of the standard cells. The leakage power consumptions of the standard cells are the static power consumption values of the standard cells corresponding to the values of predetermined static signals provided at the input of the standard cells. For example, when the delay line 108a is being designed, the static signal that will be maintained on the data output port Q1 for a major portion of the life time of the chip is determined. Assuming that the static signal to be maintained for the major portion of the life time of the chip at the data output port of the flip-flop 104a is logic 1, then the design library is searched for the standard cells that have minimum leakage power consumption for input signal of logic 1. The delay line 108a is then designed using cells from the group of minimum leakage power consumption cells. In FIG. 1A, the standard cells that satisfy the reduced or minimum leakage criteria are buffers. Thus, buffers are used to design the delay line 108a.

Referring now to FIG. 1B, the integrated circuit 100 includes the delay line 108b illustrates an example when the standard cells (buffers) present in the design library have minimum leakage power consumption for static signal of logic 0. In this case, an inverter is used as a first delay element of the delay line 108b and thereafter, since buffers have a minimum leakage power consumption for a static signal of logic 1, buffers are used as delay elements for the rest of the delay line 104b. However, since the signal to be provided to a data input port D2 of the flip-flop 104b is logic 0, the last delay element of the delay line 108b also is an inverter. Thus, the delay line 108b has a reduced or minimized leakage power consumption for a static signal of logic 0.

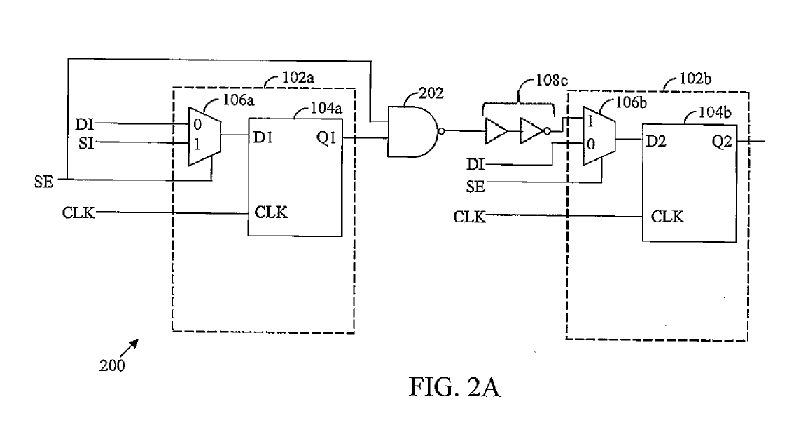

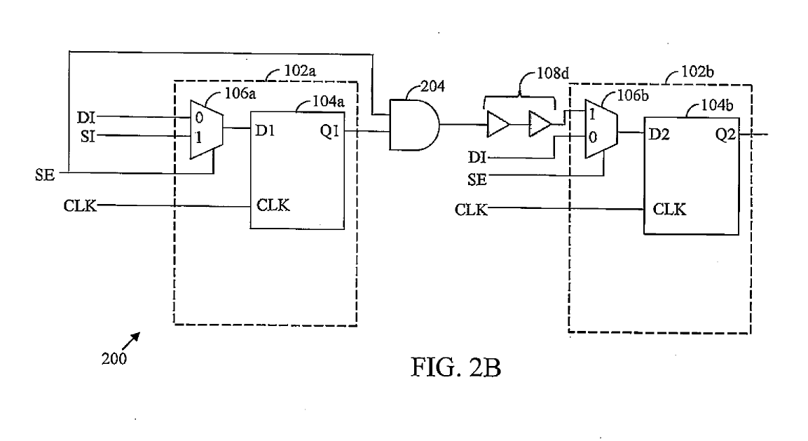

Referring now to FIGS. 2A and 2B, a schematic diagram illustrating another integrated circuit 200 in accordance with an embodiment of the present invention is shown. In addition to the elements shown in FIG. 1A, FIG. 2A the integrated circuit 200 includes a NAND gate 202 and a delay line 108c, while in FIG. 2B, the integrated circuit 200 includes an AND gate 204 and a delay line 108d.

The operation of the integrated circuit 200 is similar to the operation of the integrated circuit 100 described above. However, the integrated circuit 200 incorporates gating of the output signal from the data output port Q1 of the flip-flop 104a by the SE signal. More particularly, the SE signal and the Q1 output signal are provided to the NAND gate 202, thereby gating the output signal to logic 1. Thereafter, the delay line 108c is designed using one or more standard cells that have a reduced or minimum leakage for an input signal of logic 1. In an example, the delay line 108c is designed using a buffer and an inverter in order to reduce or minimize the leakage power consumption.

Referring now to FIG. 2B, the circuit 200 is the same as in FIG. 2A except that the NAND gate 202 has been replaced with an AND gate 204 and the delay circuit 108c has been replaced with the delay circuit 108d. In this case, the delay circuit 108d comprises a pair of buffers. Thus, in this example, the SE signal is gated with the Q1 output signal of the flip-flop 104a using the AND gate 204, which in this case gates the Q1 output signal to logic 0. Gating to logic 0 is useful in a scenario where the standard cells in the design library have leakage power consumptions that are less for an input signal of logic 0 than for an input signal of logic 1. Thus, gating to logic 0 enables the design of the delay line 108c to have reduced or minimum leakage power consumption. In an example, the delay line 108d is designed using buffers to yield minimum leakage power consumption for an input signal of logic 0.

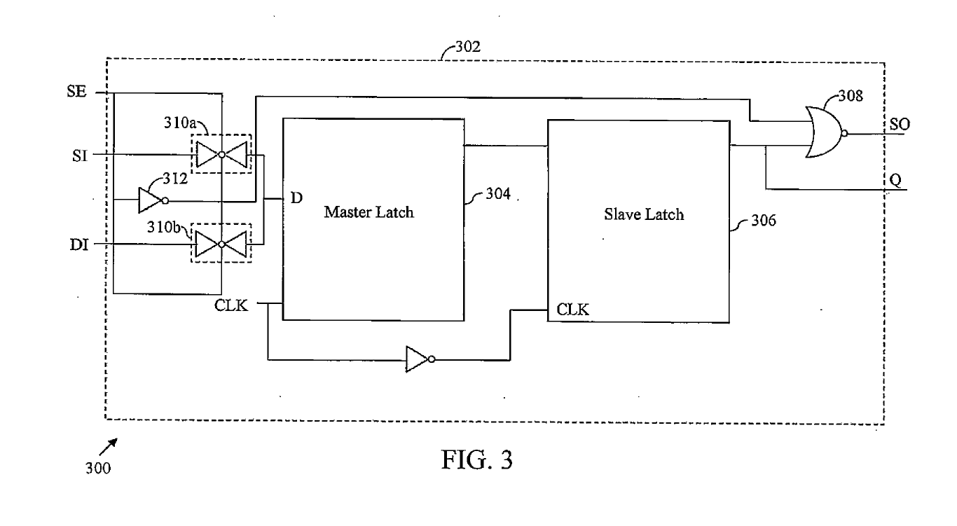

Referring now to FIG. 3, a schematic diagram of a flip-flop 300 is shown, in accordance with an embodiment of the present invention. The flip-flop 300 includes a master latch 304, a slave latch 306, a NOR gate 308, pass gates 310a and 310b, and a NOT gate 312.

The flip-flop 300 is a D flip-flop that outputs an input signal after a predetermined delay time has elapsed. A SE signal, a SI signal, a DI signal, and a CLK signal are provided to the flip-flop 302. The flip-flop 302 provides a scan output (SO) signal and a data output (Q) signal at two separate output ports. The SE signal and the SI signal are received by the pass gate 310a while the SI signal and the DI signal are received by the pass gate 310b. The pass gates 310a and 310b function as a 2-1 multiplexer and enable selection of either the SI signal or the DI signal when the SE signal is at logic 1 or logic 0 respectively. The signal selected by the pass gates 310a, 310b is provided at a data input D of the master latch 304. The operation of the master and slave latches 304 and 306 based on transitions of the CLK signal is well known in the art and is not described here for the sake of brevity.

The Q output signal is provided by the slave latch 306 to the NOR gate 308. The NOR gate 308 also receives the SE* signal, i.e., the output of the NOT gate 312. Since, the SE* signal remains at logic 1 for most of the lifetime of the chip, the SE* signal gates the output signal from the slave latch 306 to logic 0. Thus, the SO signal is maintained at logic 0 for a majority of the life of the chip. The gating of the output signal could have been done using an AND gate (see FIG. 2B), however usage of the AND gate would have led to higher leakage power consumption.

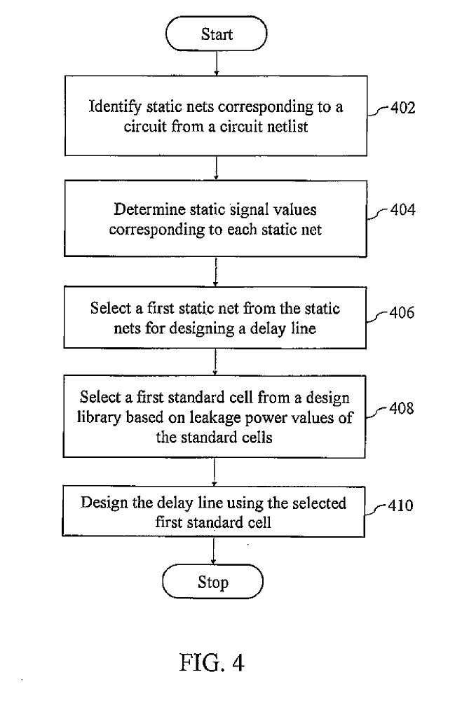

Referring now to FIG. 4, a flowchart illustrating a method for designing a delay line on a static net is illustrated, in accordance with an embodiment of the present invention. At step 402, one or more static nets are identified corresponding to a circuit from a circuit netlist. The signals on the static nets remain constant for most of the lifetime of the chip. Examples of such static nets include the signal paths carrying the SE signal that remains low during the complete lifetime of the chip except during the testing phase. Additionally, signal paths carrying signals such as clock gating test signals, reset signals, and boot signals are also examples of static nets. At step 404, static signal values corresponding to the static nets identified above are determined.

At step 406, a first static net is selected from the static nets identified above for designing a delay line therefor. At step 408, a first standard cell is selected from a design library of standard cells, based on leakage power consumption of the standard cell. That is, the design library includes a plurality of standard cells such as buffers, inverters, and so forth. The standard cells are produced for various technology nodes, as is known in the art, such as 90 nm, 65 nm, and so forth. Depending on the technology node, the standard cells have different leakage power consumptions corresponding to different input signal logic values. Since, the static nets remain at a constant logic value during most of the lifetime of the chip, the standard cell selected should be the one with the lowest leakage power consumption corresponding to the value of the static signal.

At step 410, the delay line is designed using the selected standard cell. Thereafter, more standard cells are selected using the above mentioned criteria and are appended to the delay line until the delay line is capable of providing a predetermined delay. In an example explained in conjunction with FIGS. 1A and 1B, if buffers have the lowest leakage power consumption for logic 0, the delay line is designed using buffers. In another example, if buffers have the lowest leakage power consumption for logic 1, the delay line is designed using an inverter as a first standard cell and then buffers are used as the delay elements of the remaining delay line. Finally, to restore the logic value of the static signal the last delay element of the delay line is an inverter.

Note, it should be understood by those of skill in the art that an inverter provides better power than a buffer, so, for example, suppose in a design buffers have a minimum leakage for static value 0 at their input, and the buffer tree is to be built on a net that is constant at value 1 (e.g., reset), one inverter could be used at the beginning of the chain and one at the end of the chain in order to achieve the same functionality but with improved power numbers. Here the leakage value of the inverters is not significant because even if the leakage of an inverter is more than that of a buffer, using the inverters saves the leakage power of many buffers, which are disposed between the two inverters. Further, if an inverters only chain is used, the major concern is the leakage of a cell (inverter or buffer) depends upon its input (minimum for either 1′b0 or 1′b1 at input) so if an “inverter only chain” is used it will always have alternate zeros and ones at the inverter input, which makes it very difficult to optimize leakage power. Moreover, realistically, there are typically more than four buffers/inverters in a high fanout net from source to sink.

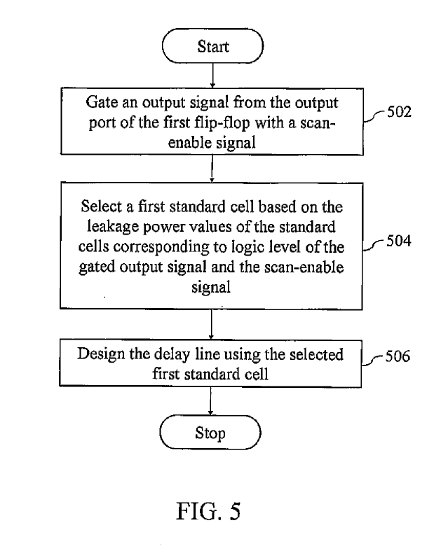

Referring now to FIG. 5, a flowchart illustrating a method for designing a delay line on a static net in accordance with another embodiment of the present invention is shown. The static net includes a data output port of a first flip-flop and a scan-input port of a second flip-flop (Refer FIG. 2A). At step 502, an output signal from the data output port of the first flip-flop is gated by a SE signal. This gating reduces dynamic power loss due to the futile toggling of the SI signal at the input port of second flip-flop (again refer to FIG. 2A) even when the SE signal is low, i.e., the IC is in a functional mode. The gating enables the SI signal provided to the second flip-flop to be maintained at a constant value when the SE signal is low.

As previously discussed, the standard cells that are used to design a delay line have different leakage power consumptions corresponding to the static signal value of the static net. Thus, the SE signal gates the output signal from the first flip-flop to a preferred logic level for which the standard cells have minimum leakage power consumption. In an example, (FIG. 2A) the SE signal and the output signal from the first flip-flop are gated using a NAND gate that gates the signals to logic 1. In another example, (FIG. 2B) the SE signal gates the output signal from the first flip-flop using an AND gate to gate the signal to logic 0. In yet another example, (FIG. 3) a SE* signal gates the output signal from the first flip-flop using a NOR gate to gate the signal to logic 0. Since, the NOR gate is formed using fewer transistors than an AND gate, the leakage power consumption of the NOR gate is less than that of the AND gate.

At step 504, a first standard cell from the one or more standard cells is selected based on the leakage power consumptions of the standard cells. Step 504 is similar to step 408 described in detail in conjunction with FIG. 4. At step 506, a delay line is designed using the standard cell selected above. Thereafter, more standard cells are selected using the above mentioned criteria and are appended to the delay line until the delay line is capable of providing a predetermined delay. Step 506 is similar to step 410 described in detail in conjunction with FIG. 4.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

What is claimed is:

1. A method for reducing leakage current of an integrated circuit, the method comprising:
generating a circuit netlist of the integrated circuit;
identifying one or more static nets of the integrated circuit from the circuit netlist;
determining static signal values of the identified one or more static nets; and
designing delay lines of the identified static nets, wherein for each identified static net said delay line designing includes:
selecting a first standard cell from a design library of standard cells based on leakage power consumptions of the standard cells, wherein the leakage power consumptions are based on a static signal value of the selected static net; and
designing the delay line using the first standard cell.

2. The method for reducing leakage current of claim 1, wherein the static nets comprise a data output port of a first flip-flop and a scan-input port of a second flip-flop, wherein the data output port provides an output signal, and wherein said delay line designing further comprises gating the output signal with a scan-enable signal.

3. The method for reducing leakage current of claim 2, wherein the output signal is gated by the scan-enable signal to either a logic one using a NAND gate, or a logic zero using an AND gate.

4. The method for reducing leakage current of claim 2, wherein the output signal is gated by a complement of the scan-enable signal to logic zero using a NOR gate.

5. The method for reducing leakage current of claim 1, wherein the one or more standard cells comprise one or more buffers and one or more inverters.

6. A method for reducing leakage power of a delay line on a static net between a data output port of a first flip-flop and a scan-input port of a second flip-flop, wherein the delay line comprises one or more standard cells selected from a standard cell library, the method comprising:
determining leakage power consumptions of the plurality of standard cells in the standard cell library;
gating an output signal from the data output port of the first flip-flop with a scan-enable signal, wherein the output signal is gated by the scan-enable signal to at least one of a logic 1 and logic 0 based on the leakage power consumptions of the one or more standard cells of the delay line;
selecting a first standard cell from the one or more standard cells in the standard cell library based on the leakage power consumptions of the one or more standard cells that correspond to the logic level of the gated output signal; and
designing the delay line using the selected first standard cell.

7. The method for reducing leakage power of a delay line on a static net of claim 6, wherein the one or more standard cells comprise one or more buffers and one or more inverters.

8. The method for reducing leakage power of a delay line on a static net of claim 6, wherein the output signal is gated by the scan-enable signal to logic 1 using a NAND gate and to logic 0 using an AND gate.

9. The method for reducing leakage power of a delay line on a static net of claim 6, wherein the output signal is gated by a complement of the scan-enable signal to logic 0 using a NOR gate.

10. An integrated circuit, comprising:
a first flip-flop, comprising:
a first data input port for receiving at least one of a data input signal and a scan input signal based on a scan enable signal; and
a data output port for providing a first output signal;
a gate for gating the first output signal by at least one of the scan enable signal and a complement of the scan enable signal, wherein the gate is at least one of an AND gate, a NAND gate, and a NOR gate, and wherein the gate provides a second output signal;
a delay line having a first end connected to the gate for providing a predetermined delay to the second output signal; and
a second data input port connected to a second end of the delay line.

11. The integrated circuit of claim 10, wherein the second data input port belongs to a second flip-flop.

12. The integrated circuit of claim 10, wherein the output signal is gated by the scan enable signal, using at least one of an AND gate and a NAND gate, to a predetermined logic level based on leakage power consumptions of the one or more selected standard cells.

13. The integrated circuit of claim 10, wherein the output signal is gated by the complement of the scan enable signal using a NOR gate.

14. The integrated circuit of claim 10, wherein the delay line comprises one or more selected standard cells that comprise at least one of one or more buffers and one or more inverters, wherein the selected standard cells are selected because they have a reduced leakage power consumption corresponding to the second output signal.
